(19) United States
(12) Patent Application Publication
(10) Pub. No.: US 2026/0330160 A1
(43) Pub. Date: Oct. 22, 2026

(54) Floquet-Based Analog Computing Devices

(71) Applicant: Northeastern University, Boston, MA (US)

(72) Inventors: Cristian CASSELLA, Boston, MA (US); Nicolas CASILLI, Kendall Park, NJ (US)

(21) Appl. No.: 19/655,662

(22) Filed: Apr. 22, 2026

Related U.S. Application Data
(60) Provisional application No. 63/792,892, filed on Apr. 22, 2025.
(60) Provisional application No. 64/045,219, filed on Apr. 21, 2026.

(51) Int. Cl. G06G 7/12; H03B 28/00; H03K 5/00

(52) U.S. Cl. CPC G06G 7/12; H03B 28/00; H03K 5/00006

(57) ABSTRACT

Floquet-based analog computing devices enhance the dynamics of parametric oscillator (PO)-based Ising machines by leveraging Floquet states that emerge spontaneously in POs coupled to high quality factor resonators. These states enable the devices to embed periodic time modulation into an energy minimization process, allowing escape from local minima during the search for solutions to quadratic unconstrained binary optimization problems. As a result, the devices significantly increase the likelihood of identifying accurate solutions compared to conventional PO-based Ising machines. The technology provides a new paradigm in analog computing, one that spans both classical and quantum computing realms, and one that can be physically realized with existing technologies.

### CROSS REFERENCE TO RELATED APPLICATIONS

This application claims the priority of U.S. Provisional Application No. 63/792,892, filed 22 Apr. 2025 and entitled “Analog Floquet Solvers for Use in Quantum Computing”, and U.S. Provisional Application No. 64/045,219, filed 21 Apr. 2026 and entitled “Floquet-Based Analog Computing Devices”. Each of the aforementioned applications is hereby incorporated by reference in its entirety.

### STATEMENT REGARDING FEDERALLY SPONSORED RESEARCH OR DEVELOPMENT

This invention was made with government support under Grant Number 2435418 awarded by the National Science Foundation. The government has certain rights in the invention.

### BACKGROUND

Solving large-scale Quadratic Unconstrained Binary Optimization (QUBO) problems is critical in various fields, including physics, finance, and engineering. However, these problems remain intractable on conventional computing architectures. Alternative solvers, such as Ising machines based on networks of coupled electronic, mechanical, or photonic parametric oscillators (POs), have recently been developed. PO-based Ising machines aim to find the ground state of an Ising Hamiltonian, which encodes the solution to a QUBO problem. However, their analog nature and their energy minimization process based on gradient descent make PO-based Ising machines inherently susceptible to identifying inaccurate solutions.

The resolution of QUBO problems holds the potential to drive significant advancements across a wide range of critical disciplines. For instance, the ability to solve large scale QUBO problems may enable a more efficient allocation of available healthcare resources [3, 4], and it may facilitate the identification of financial portfolios aligned with specific objectives, such as maximizing expected returns or minimizing financial risks [5]. Being able to solve large-size QUBO problems can also streamline the sharing of the electromagnetic spectrum among growing numbers of users with diverse needs and mutable channel conditions [6], and can assist with drug and new material synthesis and discovery [7, 8].

Unfortunately, the computational complexity of QUBO problems heavily increases with their size. As a result, traditional von Neumann computing architectures using brute-force approaches struggle to determine exact solutions to QUBO problems with more than a few dozen variables in a reasonable amount of time, owing to the exponential scaling of the solution space [9]. Consequently, there has been significant research effort around alternative algorithmic [10, 11], heuristic [6, 12], and computational methods capable of transcending the current limitations of von Neumann machines when tackling QUBO problems [13, 14, 15]. This has led to the creation of a variety of computing machines, including Ising machines [16, 17, 18, 19], which are hardware implementations of the Ising model. This model was initially conceived within the framework of condensed matter physics to study phase transitions in materials exhibiting ferromagnetism [20]. More recently, it was shown that all QUBO problems can be mapped onto networks of Ising spins [21], thus being addressable by Ising machines. This mapping allows an Ising machine to read the correct solution of a QUBO problem from the collective spin configuration with the lowest energy (the “ground state” energy).

Analog Ising machines have been developed in the form of networks of coupled oscillators, (oscillator-based Ising machines, see [18, 19]). In such machines, each oscillator can behave as an artificial spin under appropriate driving conditions, which makes oscillator-based Ising machines able to minimize the energy of the Ising model. Most reported oscillator-based Ising machines rely on free-running electronic oscillators, driven by a strong injection signal to enter an operating regime in which their phases become bistable and they start functioning as artificial spins [18, 19]. Recently, parametric oscillator (PO)-based Ising machines have been developed [32, 33, 34, 35]. PO-based Ising machines utilize POs as artificial spins. POs naturally exhibit the required bi-stability needed for computation when operating in their period doubling regime [27, 32, 36, 37], without requiring a high-power injection signal. This makes PO-based Ising machines more energy efficient than their oscillator-based counterparts, which require a strong injection-locking signal for their oscillators [18, 19]. Furthermore, POs can be implemented using passive devices that exhibit a χ⁽²⁾ nonlinearity [36, 39, 40]. PO-based Ising machines have been developed in several domains beyond electronics, including mechanical [41] and photonic [33] PO-based Ising machines. PO-based Ising machines even can be used for quantum computing [16, 30, 42, 43], an application space wherein amplifiers are typically avoided to prevent coherence losses due to their significant added noise. However, like other oscillator-based Ising machines, the accuracy achievable by PO-based Ising machines is severely impacted by convergence to and trapping in local minima of the energy landscape due to their gradient descent-like energy minimization process [44, 45].

### SUMMARY

The present technology provides Floquet-based analog computing devices, or analog Floquet solvers. The devices enhance the dynamics of parametric oscillator (PO)-based Ising machines by leveraging Floquet states that emerge spontaneously in POs coupled to high quality factor resonators. These states enable the devices to embed periodic time modulation into an energy minimization process, allowing escape from local minima during the search for solutions to QUBO problems. As a result, the present devices significantly increase the likelihood of identifying accurate solutions compared to conventional PO-based Ising machines. The technology provides a new paradigm in analog computing, one that spans both classical and quantum computing realms, and one that can be physically realized with existing technologies.

In the analog Floquet solvers provided herein, computation is carried out using a network of computational nodes, wherein each node exhibits Floquet states superimposed on the frequency comb output from a PO. Each node of the device consists of a PO coupled to a passive resonant device having a resonance frequency that closely matches, or is identical with, the PO's output frequency, effectively forming a “Floquet node” consisting of a PO-resonator pair. Thus, the analog Floquet solver contains a network of dissipatively coupled, periodically modulated nodes featuring comb-like dynamics; the network maps the specific computational problem to be solved.

The technology can also be summarized with the following list of features.
1. An analog circuit comprising a parametric oscillator coupled to a passive resonance device, wherein the circuit produces a frequency comb output in response to a pump signal input, and wherein the frequency comb comprises a Floquet state.
2. The analog circuit of feature 1, wherein the Floquet state comprises periodic amplitude modulation of the frequency comb.
3. The analog circuit of feature 1 or feature 2, which is electronic, electromagnetic, photonic, mechanical, acoustic, or a combination thereof.
4. The analog circuit of feature 3, wherein the circuit is electronic and the parametric oscillator is a parametric frequency divider.
5. The analog circuit of any of the preceding features, wherein the passive resonance device has a resonance frequency within 2% of that of the parametric oscillator.
6. The analog circuit of feature 4, wherein the passive resonance device has a resonance frequency essentially the same as that of the parametric oscillator.
7. The analog circuit of feature 4, wherein the parametric frequency divider comprises a pair of parametric oscillators coupled at their junction to a nonlinear component comprising a varactor and an inductor, and the output signal of the analog circuit is a frequency comb having a frequency that is half of a frequency of the pump signal.
8. The analog circuit of any of the preceding features, wherein the passive resonance device comprises one or more of a microelectromechanical (MEM) resonator, a piezoelectric resonator, a quartz resonator, a photonic resonator, an optomechanical resonator, a magnonic resonator, a spintronic resonator, or a resonant circuit.
9. The analog circuit of any of the preceding features, wherein the passive resonance device has a quality factor of at least five times higher than that of the parametric oscillator, or at least 500.
10. The analog circuit of any of the preceding features that resides in a chip, sensor, signal processing circuit, analog computer, or quantum computer.
11. An analog computing device comprising a plurality of the analog circuits of any of the preceding features configured as a coupled spin network, wherein each analog circuit serves as a node of the network.
12. The analog computing device of feature 11 which is capable of solving a quadratic unconstrained binary optimization problem while avoiding local minima.
13. The analog computing device of feature 11 or feature 12, wherein the device has 10 or more nodes, or 100 or more nodes.
14. The analog computing device of any of features 11-13, wherein the analog circuits of the device operate passively and do not use DC biasing.
15. The analog computing device of any of features 11-14 that is implemented in a chip, sensor, analog computer, or quantum computer.
16. The analog computing device of any of features 11-15, wherein coupling weights between the nodes are reprogrammable.
17. The analog computing device of any of features 11-16, wherein power consumption is in the nanowatt range, such as about 50 nW to about 500 nW, for each of the analog circuits.
18. A method of designing an analog computing device, comprising the steps of: providing a quadratic unconstrained binary optimization problem, which is characterized by a plurality of binary variables (spins) and can be solved by determining an arrangement of spins that provides a ground state energy level;
mapping the problem variables to the spins;
designing the analog computing device, wherein the device comprises a network of interconnected nodes, and assigning interaction strengths between nodes for solving the problem, wherein each node comprises an analog circuit of any of features 1-10.
19. The method of feature 18, wherein the problem is a problem in finance, economics, healthcare, drug discovery, material discovery, or machine learning.
20. A method of operating an analog computing device to solve a quadratic unconstrained binary optimization problem, the method comprising:
   providing the analog computing device of any of features 11-16, or the analog computing device designed by the method of feature 18 or feature 19, wherein the device is designed to solve the quadratic unconstrained binary optimization problem; and
   operating the analog computing device to find the lowest energy state, wherein two or more nodes minimize their collective Hamiltonian during phase synchronization.

### BRIEF DESCRIPTION OF THE DRAWINGS

FIG. 1A is a schematic representation of a parametric oscillator (PO)-based Ising machine featuring a system of coupled POs. POs are represented with a single mode x. FIG. 1B is a representation of the amplitude dynamics in the frequency domain of a single PO operating in the period-doubling regime under a rotating frame of ωₚ/2. FIG. 1C is a symbolic representation of the energy minimization via gradient descent implemented by PO-based Ising machines. The PO-based Ising machine is prone to convergence to sub-optimal solutions. FIG. 1D is a diagram representing a spin-solver adopting Floquet nodes as computational elements. The x modes describing POs are coupled with interaction strength, or weighting, Ji,j to map the targeted QUBO problem, while each x mode is coupled to its own unique y mode (provided by a coupled passive resonator) with strength g. FIG. 1D-1 is an enlargement of a portion of FIG. 1D, showing node 100 having parametric oscillator 110, to which is coupled passive resonance element 120. FIG. 1E shows the simulated frequency spectrum normalized around ωₚ/2 of the mode x of the analog Floquet solver operating with Floquet states. The periodic modulations of the system generate a frequency comb. FIG. 1F presents a symbolic comparison of the energy minimization profiles of the PO-based Ising machine and the analog Floquet solver in normalized time. The periodicity of the analog Floquet solver's energy minimization profile illustrates the energetic oscillatory behavior provided to the system. FIG. 1G is a representation of the coordinated cycling of a subset of Ising energies undertaken by the analog Floquet solver (AFS) during the final stages of the computation, compared with those explored by Ising machines (PO-IM).

FIG. 2A is a circuit schematic of a parametric frequency divider, which is an electronic realization of a parametric oscillator. The parametric frequency contains two LC tanks connected at their junction to a nonlinear element, such as a varactor combined with an inductor. FIG. 2B schematically shows the time domain waveform of the output of the parametric frequency divider when driven at fₚ with a signal amplitude above the voltage threshold required to trigger subharmonic oscillations. FIG. 2C schematically shows the corresponding frequency spectrum of the output signal of the parametric frequency divider centered around fₚ/2, showing that the system is operating in the period-doubling regime.

FIG. 3A shows a modified Butterworth Van Dyke model of the equivalent circuit of a high-Q microelectromechanical (MEM) resonator used in an analog Floquet solver. FIG. 3B is a circuit schematic of an electronic realization of a Floquet node, constructed by coupling a MEM resonator to the output of a parametric frequency divider. FIG. 3C shows the time domain waveform of the output of the Floquet node of FIG. 3B when driven at fₚ with a signal amplitude identical to the one used to drive the parametric frequency divider; as can be seen, the output signal is modulated. FIG. 3D shows the corresponding frequency spectrum of the output signal of the Floquet node centered around fₚ/2, showing that the system exhibits Floquet states.

FIG. 4A is a plot showing the Ising energy over time (H_{Ising}) of a PO-based Ising machine compared with an analog Floquet solver in normalized time. FIG. 4B is a plot of the spin states accessed by the PO-based Ising machine throughout the entirety of its computation. In this instance, the spin-solver failed to reach the ground state energy value. FIG. 4C is a plot of the states accessed by the analog Floquet solver throughout the entirety of its computation. The spin-solver identified all degenerate ground states. FIG. 4D is a plot showing the number of times a certain energy level was accessed by the PO-based Ising machine and the analog Floquet solver. The PO-based Ising machine had only a limited exposure to lower energy levels, while the analog Floquet solver operated mostly in the lower energy levels.

FIG. 5A shows the extracted spin state of the x₁ node, σ₁, shown throughout a small range of the simulation time. As can be seen, once the analog Floquet solver switches from operating in the period doubling regime and begins to exploit its nodes' Floquet states, σ₁ regularly flips its spin state. FIG. 5B shows the extracted spin states σᵢ of all the nodes, showing how the system's spins collectively undergo periodic changes of state. FIG. 5C shows the Ising energy of the system throughout the entire simulation. While the system initially converges to a local minimum while operating as a PO-based Ising machine, the activation of Floquet states enables the system to eventually identify the problem's ground state spin configuration by escaping the previously identified local minimum. Time, in these plots, is normalized over the entire simulation window.

FIGS. 6A-6F show numerically computed trends for the PO-based Ising machine (POIM) and the analog Floquet solver (AFS). These trends show the obtained P_{success} and Ts values over 100 iterations for: (FIGS. 6A-6B) the set of 60 node BiqMac Max-Cut problems; (FIGS. 6C-6D) the set of 80 node BiqMac Max-Cut problems; and (FIGS. 6E-6F) the set of 100 node BiqMac Max-Cut problems. Agnostic to the problem instance, the analog Floquet solver achieved higher p_{success} with lower Tₛ than the PO-based Ising machine counterpart.

FIGS. 7A-7G show numerically computed cut distributions for the PO-based Ising machine and the analog Floquet solver when solving the following 2000 node Gset problems: FIG. 7A, G32; FIG. 7B, G33; FIG. 7C, G34; FIG. 7D, G35; FIG. 7E, G36; FIG. 7F, G37; and FIG. 7G, G38. As can be clearly seen, the analog Floquet solver computed a dramatically higher cut size than the PO-based Ising machine. In many of the observed instances, the distributions of cuts did not overlap at all, meaning that the worst solution obtained by the analog Floquet solver was still better than the best solution obtained by the PO-based Ising machine.

FIG. 8 shows numerically extracted trends of Nₛ (normalized to the best known solution) averaged over 100 runs for Gset problems G01-G64 and G67. The shaded region shows the range of the minimum and maximum runs for each problem for both solvers.

FIG. 9A shows numerically extracted H_{Ising} when considering fs=180μ and fs=9μ for a randomly generated 200-node 3-regular problem graph. Specifically, H_{Ising} is centered around the middle of the computation time. The resolution of H_{Ising} dramatically worsens with a twentyfold reduction in fs. FIG. 9B shows the numerically extracted relationship between H̅min and fs for the PO-based IM (Period Doubling) and the analog Floquet solver (AFS). As fs decreases, the solution quality of the AFS goes through a commensurate degradation. For fs>μ/4, the AFS reliably accesses better quality solutions than the PO-based TM.

FIGS. 10A-10J show numerically extracted trends of A̅H̅ and Ising energy for (10A) g05_60.0, (10B) g05_60.1, (10C) g05_60.2, (10D) g05_60.3, (10E) g05_60.4, (10F) g05_60.5, (10G) g05_60.6, (10H) g05_60.7, (10I) g05_60.8, and (10J) g05_60.9.

FIGS. 11A-11J show numerically extracted trends of A̅H̅ and Ising energy for (11A) g05_80.0, (11B) g05_80.1, (11C) g05_80.2, (11D) g05_80.3 (11E) g05_80.4, (11F) g05_80.5, (11G) g05_80.6, (11H) g05_80.7, (11I) g05_80.8, and (11J) g05_80.9.

FIGS. 12A-12J show numerically extracted trends of A̅H̅ and Ising energy for (12A) g05_100.0, (12B) g05_100.1, (12C) g05_100.2, (12D) g05_100.3, (12E) g05_100.4, (12F) g05_100.5, (12G) g05_100.6, (12H) g05_100.7, (12I) g05_100.8, and (12J) g05_100.9.

FIG. 13 shows numerically extracted distributions of PM, LM, and GS solutions from (top panel) 60 node BiqMac problems g05_60.0-g05_60.9, (middle panel) 80 node BiqMac problems g05_80.0-g05_80.9, and (bottom panel) 100 node BiqMac problems g05_100.0-g05_100.9 when solved by both the PO-based IM and the AFS.

### DETAILED DESCRIPTION

The present technology provides a path toward the resolution of NP-hard combinatorial optimization problems by exploiting a novel analog computing engine never reported before. In this engine, namely an “analog Floquet solver” (AFS), each computational unit is an analog circuit capable of exciting a Floquet state, which is a periodic amplitude modulation of a frequency comb output of a parametric oscillator (PO).

Connecting more computational units based on a specific problem that is to be solved allows Floquet solvers to reach the lowest energy state of the network, corresponding to the solution of the problem. This is different from any other analog machine developed in the past, because the pursuit of such minimum energy states occurs while the quasi-periodic behavior of each Floquet unit allows the avoidance of getting stuck in local minima (i.e., sub-optimal solutions), which is the limitation of previous analog computational devices.

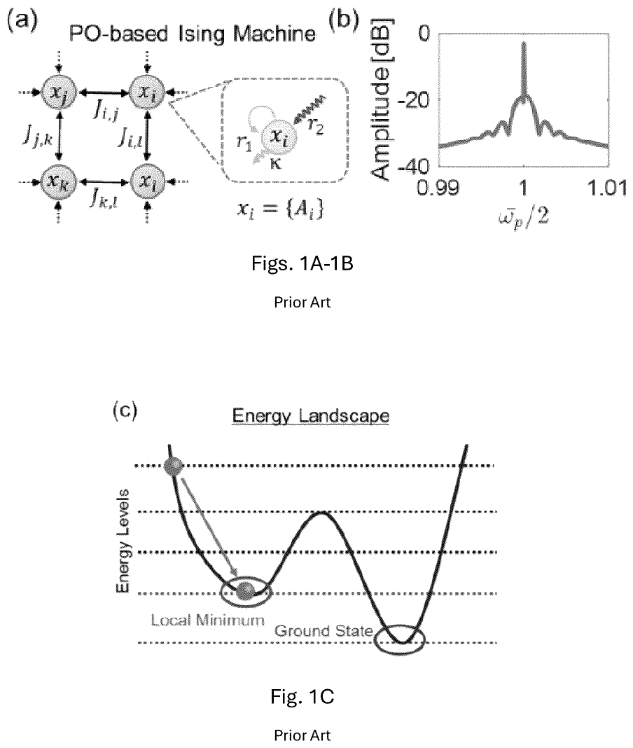

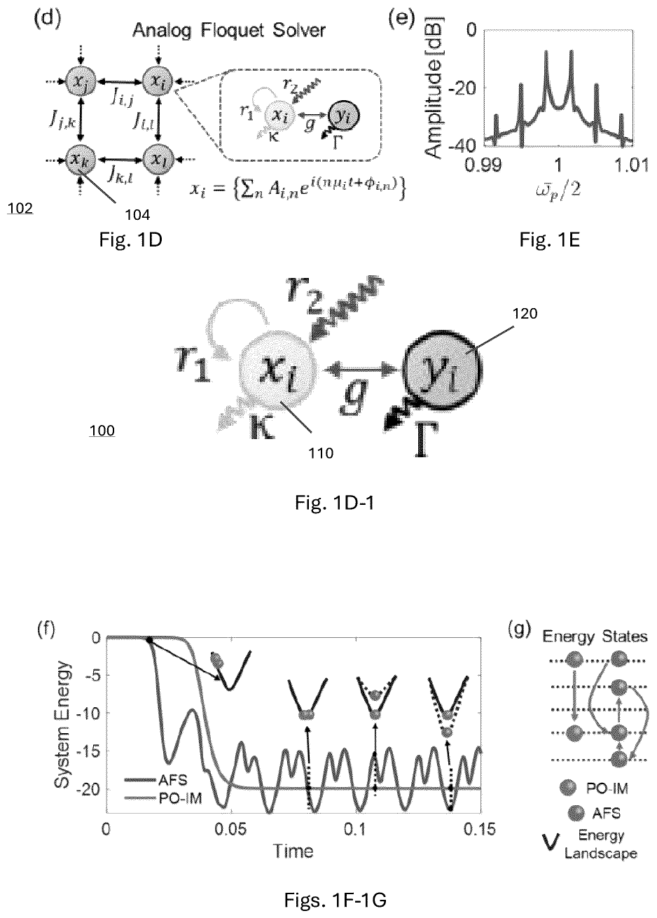

In an AFS according to the present invention, each node consists of a PO coupled to a passive resonant device with resonance frequency that closely matches the PO's output frequency, effectively forming a “Floquet node” consisting of a PO-resonator pair. FIG. 1D-1 shows a representation of a generic AFS node 100, containing PO 110 and resonator 120. FIG. 1E shows a typical spectrum of the PO output from an AFS node, xᵢ.

The present Floquet nodes only require one resonator symmetrically coupled to one PO. Other approaches can be used, such as anti-symmetric coupling in PO networks, which can generate additional time-dependent modulation, but such approaches introduce significant implementation complexity. For the AFS to tackle a QUBO problem, a coupling scheme between all Floquet nodes must be engineered to reflect the problem graph. In this regard, a coupling matrix [J] can be assembled, defining the interactions between all computational nodes, as depicted in FIGS. 1A and 1D. Each coefficient Ji,j captures the coupling strength between two specific nodes (with indices i and j). As required for PO-based IMs, the AFS requires all its nodes to be continuously driven by a single-tone pump signal during the computation, which causes all the AFS's nodes to collectively pursue lower energy states as soon as the computation starts. Furthermore, the Floquet dynamics in the AFS do not result from the beating between a continuous wave signal and a lower-frequency modulation signal, as in conventional Floquet systems. Instead, they emerge from the activation of frequency combs in all the nodes of the AFS, caused by the same parametric nonlinearities that induce period-doubling in PO-based Ising machines.

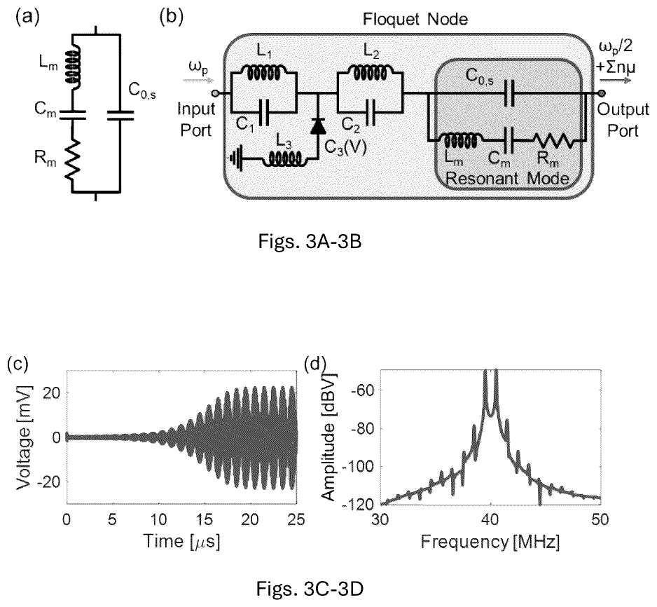

The nodes of an AFS are coupled through their output signals. In an electronic implementation, such as using analog circuits like that shown in FIG. 3B, the Floquet nodes can be coupled using resistive or reactive elements via their outputs. The interaction strength between nodes can be adjusted or reprogrammed using circuit elements like voltage-dependent potentiometers or voltage-dependent ferroelectric MFM capacitors to tune the coupling strength using an applied voltage. For implementations in optics one can use, for example, field-programmable gate array (FPGA)-enabled pulse coupling in fiber optic cables, wherein the FPGAs can change the coupling weights via digital programming. In a photonics implementation, reconfigurable beam-splitters can be used to adjust coupling strength between nodes.

Unlike PO-based Ising machines, the energy minimization process of the AFS does not follow a gradient descent. Instead, with all the AFS nodes supporting a Floquet state, the process is governed by a combination of gradient descent and periodic oscillations of the overall energy landscape. The AFS energy landscape periodically oscillates following the periodic drive of the Floquet states (see FIG. 1F). Like PO-based Ising machines, the AFS encodes the solution of the associated QUBO problem into the ground state of an Ising Hamiltonian, which represents the energy landscape

$${H}_{Ising} ( t ) = \frac{1}{2} {\sum }_{i , j}^{N} {σ}_{i} ( t ) {J}_{i , j} {σ}_{j} ( t )$$

where σᵢ and σⱼ are the digitized spin values representing the amplitude and phase solutions for the AFS nodes of indices i and j respectively, and N is the total number of nodes in the problem graph. The periodic variations of the AFS energy landscape induced by the Floquet drive results in synchronized flips of all o-values (from a “spin-up” or “+1” configuration to a “spin-down” or “−1” configuration and vice versa). These flips result in deterministic and periodic changes in the discretized Ising energy level reached during the computation. This allows the computation to reach more accurate solutions than those identified by PO-based Ising machines when tackling large-size QUBO problems. In turn, the AFS never settles to a final steady-state collective spin configuration, as seen in FIG. 1G. This marks an important distinction between the AFS and conventional PO-based Ising machines (see also FIG. 1F).

In the examples presented below, the computational principles of the AFS are presented, and it is demonstrated how the Floquet dynamics of the AFS allow it to solve QUBO problems with varying densities. The BiqMac and Gset libraries are exemplified and analyzed [28], [46], [47], and it is shown that the AFS can solve them more accurately than conventional PO-based Ising machines. It is also demonstrated how the ability to escape local minima originates from a reduction of the impact of AH on the solution accuracy and produces substantially improved capabilities to ascertain optimal or near-optimal solutions to QUBO problems than what is achievable when using PO-based Ising machines. The improved computational performance is achieved while requiring only marginal amounts of space and power overhead to generate the Floquet states (e.g., only one extra passive resonator per PO is needed compared to traditional PO-based Ising machines).

### EXAMPLES

### Example 1. Nonlinear Dynamics of Floquet Nodes

Temporal coupled mode theory [48] was applied to analyze the dynamics of a PO-resonator pair forming the computational node of an AFS. Considering the analytical model depicted in FIG. 1D, a Floquet node can be treated as a triply resonant mode, containing a pump mode xₚ and a signal mode x, which are parametrically coupled through a second order χ⁽²⁾ nonlinearity, and an external resonant mode y with a loss-rate Γ. Like any resonant mode studied using temporal coupled mode theory, the evolution of y can be simply modelled by using a first-order differential equation:

$$\dot{y} ( t ) = - \frac{Γ}{2} y ( t )$$

When neglecting y, the behavior of the system in FIG. 1D coincides with that of a PO and can be modelled, after applying adiabatic elimination, using a single differential equation:

$$\dot{x} ( t ) = - ( \frac{κ}{2} + {r}_{1} {\vert x ( t ) \vert}^{2} ) x ( t ) + {r}_{2} {x}^{*} ( t )$$

On the other hand, in Floquet nodes, x is strongly coupled to y via a linear coupling term g, but the resonant mode y is uncoupled to the pump mode xp, as seen in FIG. 1D. Additionally, to synthesize the strong coupling between x and y modes that is required to generate the Floquet state, g must exceed Γ/2 [40]. This permits to once again use adiabatic elimination to express the dynamics of a single Floquet node by using a system of two equations that describe the temporal evolution of the x and y modes (Eqs. 1a, 1b) when relying on rotational frames, e.g.,

$$x ( t ) \to x ( t ) {e}^{- ι ( π / 4 )} , x ( t ) \to x ( t ) {e}^{- ι ( {ω}_{p} / 2 ) t} , and$$

$$y \to y ( t ) {e}^{- i ( {ω}_{p} / 2 ) t} ) .$$

$$\dot{x} ( t ) = - ( \frac{κ}{2} + {r}_{1} {\vert x ( t ) \vert}^{2} ) x ( t ) + {r}_{2} {x}^{*} ( t ) - igy ( t ) , \qquad ( 1 a )$$

$$\dot{y} ( t ) = - \frac{Γ}{2} y ( t ) - igx ( t ) . \qquad ( 1 b )$$

In this system, r₁ is the gain saturation coefficient, r₂ is the small-signal gain parameter, and K is the loss-rate of the x mode. Similar to a conventional PO, a Floquet node can also access a period-doubling regime for sufficiently large values of r₂; however, it enters an additional nonlinear regime for lower r₂ values in which x and y manifest modulations of their amplitudes. Because of these modulations, x and y have a frequency spectrum featuring a frequency comb centered around ωₚ/2, as seen in FIG. 1E. In this regime, the x and y slow varying complex amplitudes can be represented using Floquet theory as

$$x ( t ) = {\sum }_{n = - ∞}^{∞} {A}_{n} ( t ) {e}^{i ( n μ t + {ϕ}_{n} ( t ) )}$$

$$and$$

$$y ( t ) = {\sum }_{n = - ∞}^{∞} {B}_{n} ( t ) {e}^{i ( n μ t + {θ}_{n} ( t ) )}$$

where n represents the index of the Floquet multipliers ei(nμt+θn(t)) that elegantly capture the Floquet node's comb-like behavior. An(t), Bn(t), φn(t), and θn(t) describe the amplitudes and phases of the nₜₕ Floquet harmonic of the x and y modes respectively, while μ, which varies with respect to g and r₂, is the Floquet exponent. The periodicity of the x and y modes indicates that the Floquet node operating in this frequency comb regime features a classical Floquet regime [49]. Considering x (through which σ is extracted) to be purely real due to the rotational frame and lack of detuning [40], this mode can be expressed as

$$x = {\sum }_{n = 1}^{∞} {A}_{n} cos ( n μ t + {ϕ}_{n} )$$

$$( FIG . 1 E ) .$$

For the sake of brevity, the time dependence of the mode amplitudes and phases is omitted in the following. It is important to note that μ varies inversely with respect to r₂, eventually converging to 0 for a sufficiently large r₂ values [40].

To demonstrate the computational capabilities of the AFS, the dynamics of large-scale, dissipatively coupled networks of identical (i.e., κi=κ, Γi=Γ, and gi=g) Floquet nodes were analyzed. In addition, stochastic Brownian noise was introduced in the system of equations, analogous to the Johnson noise introduced in the electrical PO-based Ising machine studied in [32]. Such a process is represented with a scalar, N_{b}, modelling the magnitude of the noise, while ζi,x and ζi,y represent Gaussian white noise with zero mean for the iₜₕ x and y modes respectively [50]. Overall, this modelling approach permits describing the dynamics of N Floquet nodes with 2N equations.

$${\dot{x}}_{ι} = - ( \frac{κ}{2} + {r}_{1} {\vert {x}_{i} \vert}^{2} ) {x}_{i} + {r}_{2} {x}_{i}^{*} - {igy}_{i} - {\sum }_{i \neq j}^{N} {J}_{i , j} {x}_{j} + {N}_{b} {ζ}_{i , x} , \qquad ( 2 a )$$

$${\dot{y}}_{ι} = - \frac{Γ}{2} {y}_{i} \to {igx}_{i} + {N}_{b} {ζ}_{i , y} . \qquad ( 2 b )$$

By excluding Eq. (2b) and setting yᵢ=0, a similar system of equations can be devised to model the dynamics of N coupled POs.

### Example 2. Principle of Computation

To verify that the AFS can efficiently tackle NP-hard QUBO problems, we must first determine the cost function that is minimized by the system's collective dynamics. Then, we must demonstrate that the cost function's interaction term is structurally compatible with the Ising Hamiltonian[27], [44]. In this regard, the interaction term of a cost function describes the system's collective behavior. Hence, an interaction term closely aligned with the Ising Hamiltonian indicates that the minimization of the system's energy corresponds to the minimization of the Ising Hamiltonian, thereby yielding the potential for the system to solve QUBO problems. To this end, we report a cost function _{FC(x1}, x1*, y1, y1*, . . . , yN, yN*) [51, 52], derived from Eq. (2a) and Eq. (2b), which is effectively a 4N-dimensional space comprised of each mode and its complex conjugate. When excluding the noise terms, Nbζi,x and Nbζi,y, this function takes the form

$${F}_{c} = {\sum }_{i}^{N} [ \begin{matrix}( \frac{κ}{2} ) {\vert {x}_{i} \vert}^{2} + ( \frac{Γ}{2} ) {\vert {y}_{i} \vert}^{2} + \frac{{r}_{1}}{2} ( {\vert {x}_{i} \vert}^{4} ) - \\ \frac{{r}_{2}}{2} ( {x}_{i}^{2} + {x}_{i}^{* 2} ) + i g ( {x}_{i}^{*} {y}_{i} + {x}_{i} {y}_{i}^{*} )\end{matrix} ] + \frac{1}{2} {\sum }_{i \neq j}^{N} {x}_{i}^{*} {J}_{i j} {x}_{j} \qquad ( 3 )$$

F_{c} also obeys

$$- \frac{\partial {F}_{C}}{\partial {x}_{i}^{*}} = \dot{{x}_{ι}} , - \frac{\partial {F}_{C}}{\partial {x}_{i}} = \dot{{x}_{ι}^{*}} , - \frac{\partial {F}_{C}}{\partial {y}_{i}^{*}} = \dot{{y}_{ι}} ,$$

and [51, 52]
*

$$- \frac{\partial {F}_{C}}{\partial {y}_{i}} = \dot{{y}_{ι}^{*}}$$

which is important because this property affirms indeed that Fc (and therefore the Ising Hamiltonian) is minimized by the AFS throughout its evolution.

The minimization of Fc occurs through two processes: through the self-sustaining oscillations of each individual Floquet node and through the coupled interactions between nodes [51]. The interaction term, referred to as

$$η = \frac{1}{2} {\sum }_{i \neq j}^{N} {x}_{i}^{*} {J}_{i , j} {x}_{j}$$

encodes the energy landscape (or energy potential) of the AFS and is intended to map the QUBO problem being solved via the coupling scheme configured by the matrix [J]. When substituting the periodic solutions of xᵢ and xⱼ into η, it can be expressed as:

$$η = \frac{1}{2} {\sum }_{i , j} [ {J}_{i , j} {\sum }_{n = 1}^{∞} {A}_{i , n} cos ( n {μ}_{i} t + {ϕ}_{i , n} ) {\sum }_{m = 1}^{∞} {A}_{j , m} cos ( m {μ}_{j} t + {ϕ}_{j , m} ) ] \qquad ( 4 )$$

This expression can be further simplified by assuming μᵢ=μⱼ=μ (all Floquet nodes have the same characteristic Floquet exponent for simplicity), and n=m=1 (only considering the first Floquet harmonic since its amplitude is much larger than the amplitude of the other harmonics). In this scenario, η can be decomposed into two terms, representing parallel interaction dynamics, expressed separately as η₀ and η₁ in Eqs. (5a) and (5b) such that η=η₀+η₁.

$${η}_{0} = \frac{1}{4} {\sum }_{i \neq j}^{N} [ {I}_{i , j} {A}_{i , 1} {A}_{j , 1} cos ( {ϕ}_{i , 1} - {ϕ}_{j , 1} ) ] , \qquad ( 5 a )$$

$${η}_{1} = \frac{1}{4} {\sum }_{i \neq j}^{N} [ {J}_{i , j} {A}_{i , 1} {A}_{j , i} cos ( 2 μ t + ( {ϕ}_{i , 1} + {ϕ}_{j , 1} ) ) ] . \qquad ( 5 b )$$

The term η₀ retains a structure similar to a typical PO-based Ising machine's interaction term [27,46]

$$( {η}_{PO} = \frac{1}{2} {\sum }_{i \neq j}^{N} {J}_{i , j} {x}_{i} {x}_{j}$$

imposing a gradient descent-like evolution akin to that leveraged by PO-based Ising machines [44]. On the other hand, η₁ introduces a slow periodic oscillation in η due to the modulation of the nodes' amplitudes (see FIG. 1F). Furthermore, the instantaneous contribution of η₁ to η may be either positive or negative, leading to a Floquet modulation of the AFS's energy over time. It is η1 that endows the AFS with the ability to escape local minima in H_{Ising} as it evolves to minimize η. Note that in this discussion, η is analog in the sense that it considers the amplitude and phase components of the node solutions as its inputs, whereas QUBO problems are digital, with binarized values as inputs. To properly understand the relationship between minimizing η and solving QUBO problems, the information encoded in each Floquet node must be digitized as a value σᵢ in {+1, −1}. Such digitization permits converting the continuous solutions obtained for it into discrete solutions for H_{Ising}. The digitization process entails replacing the analog amplitudes x₁ in 11 with the corresponding spin values, computed as

σᵢ=sign(ΣₙA_{i,n}(t)cos(nμt+φ_{i,n})

This permits the transformation of

$$η = \frac{1}{2} {\sum }_{i \neq j}^{N} {x}_{i}^{*} {J}_{i , j} {x}_{j}$$

$$into$$

$${H}_{Ising} = {\sum }_{i \neq j}^{N} {σ}_{i} {J}_{i , j} {σ}_{j}$$

The digitized a values exhibit the same time periodicity of the continuous x. As a result, while the AFS minimizes η₀ in η to optimize H_{Ising}, all a values keep changing from +1 and −1 (and vice versa) at a rate equal to p. Such periodic changes of a can help the AFS to escape local minima in H_{Ising} by correspondingly cycling through different sets of spin configurations, including degenerate ground states of H_{Ising}.

### Example 3. Energy Minimization Dynamics with Randomized Initial Conditions

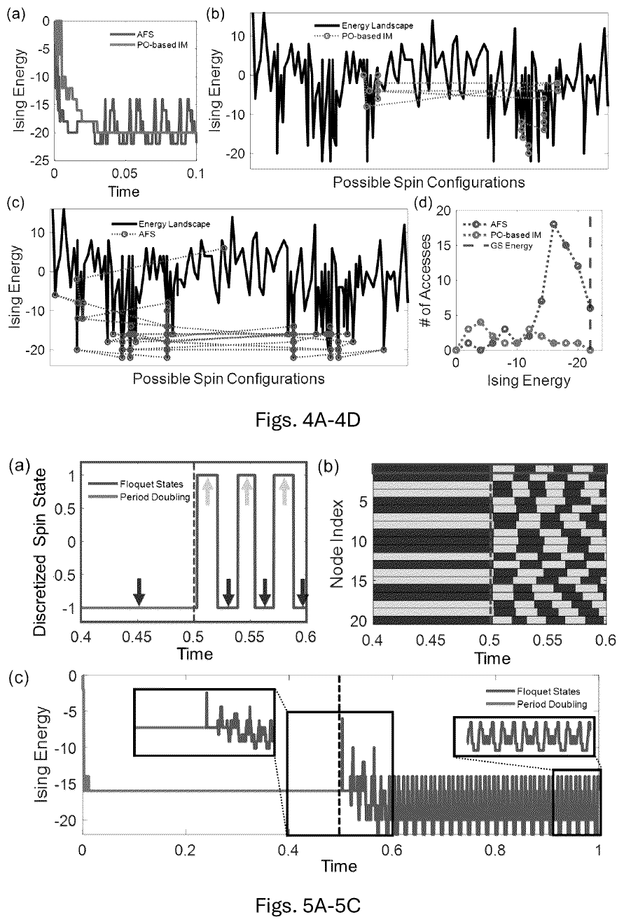

The AFS was compared to a PO-based Ising machine when solving a randomly generated 20-node 3-regular Max-Cut problem [32], [34], [53] with a pre-computed ground state Ising energy of −22. The test began with a small-scale problem because it allows for a clearer investigation of the computational dynamics compared to large-scale problems. After configuring the matrix [J] in accordance with the Max-Cut problem to be solved, both the AFS and the PO-based Ising machine were activated by applying r₂=0.7κ. Then, the digitized spin states of all nodes were tracked during the computation, and these were used to extract H_{Ising} at each timestep, as shown in FIG. 4A. During this computation, it could be seen that the PO-based Ising machine converged to a local minimum (−20) as it reached its steady state. In contrast, the AFS underwent its own gradient descent augmented by Floquet modulations in its energy. This allowed the AFS to access a diverse range of energy states and, most importantly, to periodically reach the ground state. To visualize how η₁ influences the Ising energy level reached during the computation and helps avoid getting trapped in a local minimum of H_{Ising}, the temporal evolution was examined for the identified spin configuration and the corresponding H_{Ising} value for both the AFS and the PO-based Ising machine. To this end, in FIGS. 4B and 4C are plotted the Ising energy landscape associated with the problem being solved. This was done by determining the value of the Ising energy achieved when considering different configurations of N=20 spin values ranging from {−1−1−1 . . . −1−1−1} to {+1+1+1 . . . +1+1+1}. Overlaid on the landscape, the specific spin-configurations identified by the PO-based Ising machine and the AFS were marked throughout their computation.

As already observed in FIG. 4A, the value of H_{Ising} identified by the PO-based Ising machine followed a gradient descent profile, with some noise-induced fluctuations in energy during the early stages of its computation. On the other hand, the energy evolution profile of the AFS demonstrated some trending to a classical gradient descent routine during its early computational stages. However, once the identified H_{Ising} had reached the low energy portion of the landscape (thus, the region where the PO-based Ising machine was liable to get stuck in local minima), the Floquet dynamics of the AFS became more evident and, as a result, the AFS began cycling through a recurring set of low-energy spin configurations. Evidently, during this phase, the AFS identified a broad range of spin configurations, corresponding to energy levels that are lower than the lowest energy obtained by the PO-based Ising machine, including all six degenerate ground state solutions [16] of the targeted problem.

An additional quantitative comparison between the analyzed PO-based Ising machine and the AFS was performed by evaluating the quality of the solutions they identify over the course of the entire computation-defined, for the AFS, as the interval from the start of the computation to the end of the second period of the temporal modulation observed in H_{Ising}. In this comparison, a solution is considered to be of higher quality if its energy value is lower and closer to the ground state. Likewise, a solver is deemed more accurate if it consistently identifies spin configurations with H_{Ising} values nearer to the ground state. To quantify the superiority of the AFS to the PO-based Ising machine architecture, every unique instance was recorded when either solver accessed an Ising energy level between 0 and −22, as shown in FIG. 4D. It was discovered that the AFS predominantly operated in low-energy regions of the landscape, permitting the AFS to identify many spin configurations with Ising energy close to the ground state. On the other hand, the PO-based Ising machine progressively accessed fewer spin configurations (especially those with low energy) as the spin-solver approaches the ground state. This bias in the AFS towards identifying lower energy values occurs due to the modulation process, instantiated by η₁, generally occurring after the initial energy minimization mediated by η₀.

In summary, the AFS identified a significantly larger quantity of optimal and near-optimal solutions than the PO-based Ising machine during the same computation time. This capability can be especially valuable when solving QUBO problems in time- or power-sensitive applications where optimal or near-optimal solutions are sufficient.

### Example 4. Floquet Amplitude Modulations to Escape Local Minima

As another validation of the AFS's capabilities to escape local minima in H_{Ising} and achieve lower energy solutions than PO-based Ising machines, the ability of AFS to operate as a PO-based Ising machine for significantly larger pump power levels (i.e., for higher r₂ values) than those needed to trigger the Floquet states in its nodes was investigated. As before, a 20-node 3-regular Max-Cut problem (the same analyzed in FIG. 4D) was used. Differently from before, r₂ was initially configured to a sufficiently large value to activate the period-doubling regime in all the AFS's nodes. After enough time had elapsed for the system to reach its steady state (at a normalized time (t) equal to 0.5, see FIGS. 5A and 5B), r₂ was abruptly reduced and Floquet states activated in all the AFS nodes. The spin states were monitored, and it was noted that the activation of Floquet states corresponded with a synchronized change of the spin values of all the AFS nodes, as seen in FIG. 5B. Then, H_{Ising} was computed and it was determined that the AFS, while operating in the period-doubling regime, reached a local minimum Ising energy of −16, as seen in FIG. 5C.

Once the Floquet states were activated through the abrupt reduction of r₂, H_{Ising} started to vary periodically which, notably, significantly enhanced the AFS's ability to identify the ground state Ising energy (−22) and helped the system escape the previously attained energy local minimum (see FIG. 5C). This demonstrates that the energetic oscillations in η induced by the activation of the Floquet states provides a path for the AFS to identify the ground state spin-configuration, allowing the AFS to overcome the computational limits of PO-based Ising machines. During the period doubling regime, the system energy undergoes a very sharp minimization before converging to a local minimum, indicative of the behavior of a gradient descent search. The subsequent emergence of the Floquet states and synchronized collective spin flips leads the AFS to undergo substantial movements throughout the energy landscape, mostly localized proximate to optimal or near-optimal solutions.

### Example 5. Benchmarking the AFS Against PO-Based Ising Machines in Mid- and Large-Scale Problems

The analysis depicted in FIGS. 4A-4D and 5A-5C allowed visualization of the main differences in the computation between the AFS and the PO-based Ising machine. Nonetheless, a more meaningful quantitative comparison of these two QUBO solvers requires testing their performance when attempting to solve larger-scale and more densely connected QUBO problems. To do so, the performance of the AFS with was compared with that of a PO-based Ising machine when tackling mid-scale Max-Cut problems from the BiqMac library [47], [54] and large-scale Max-Cut problems from the Gset library. These problems are commonly used for benchmarking the performance of Ising machines. In particular, the BiqMac “g” series problems with graph sizes of 60 nodes, 80 nodes, and 100 nodes were solved. Each was solved numerically 100 times using both the AFS and the PO-based Ising machine when considering the initial node amplitudes to be randomly distributed between −10⁻⁵ and 10⁻⁵. For both machines, a fixed pump signal amplitude of 0.7κ was applied without running any annealing, and the instantaneous cut size was computed as identified by both machines during their computation.

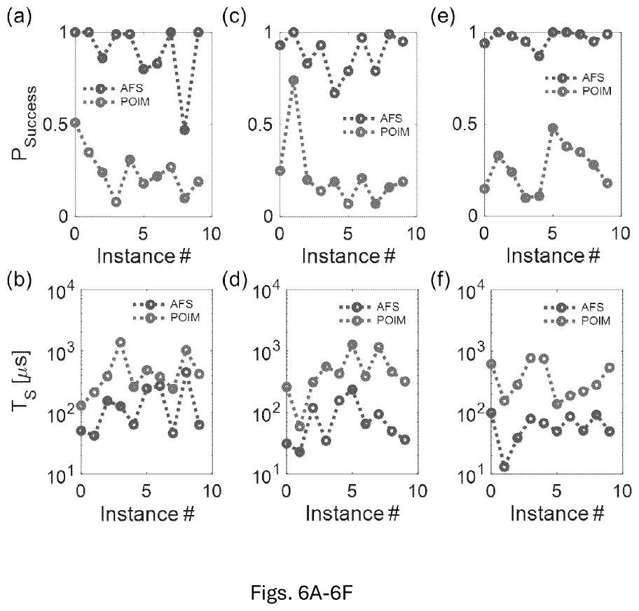

Because the BiqMac library problems have known exact solutions expressed in terms of number of cuts, it was possible to calculate the probability of success, P_{success}, which was defined as the number of runs that identified a cut solution within 0.5% of the analytical maximum cut divided by the total number of runs for each problem. The time to solution, Ts, was also calculated; this is the expected time required to find a solution within 0.5% of the optimal one. The computation for Ts required us to track τᵣ, which is the runtime of the AFS or the PO-based Ising machine. Both P_{success} and Ts are plotted in FIGS. 6A-6F. Specifically, the results of the 60 node problems are shown in FIGS. 6A and 6B, the results of the 80 node problems are shown in FIGS. 6C and 6D, and the results of the 100 node problems are shown in FIGS. 6E and 6F. As can be seen, the AFS offers a significant improvement both in the form of an increased P_{success} and a reduced Ts compared to the PO-based Ising machine across all problem instances and problem sizes.

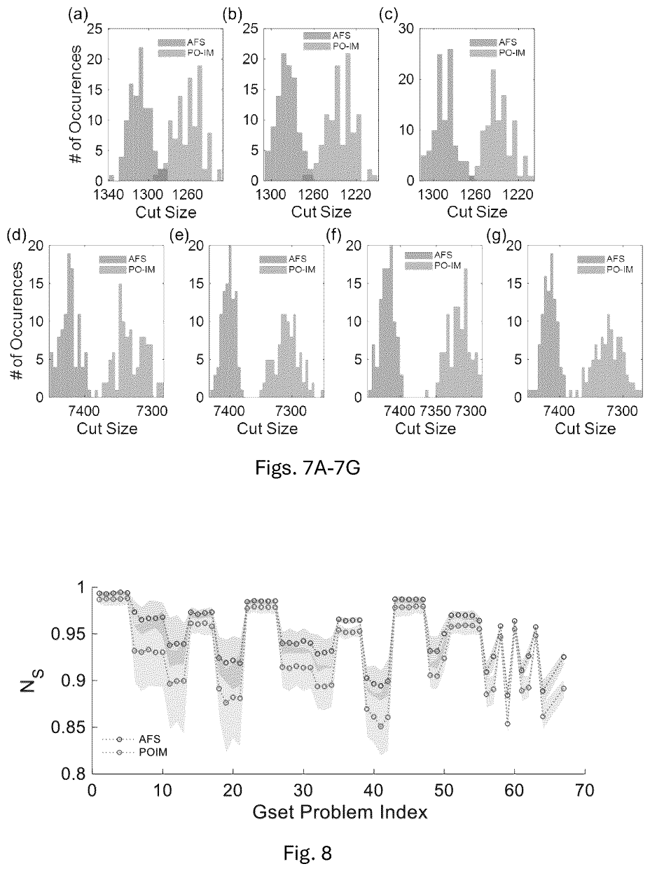

Next, the AFS and the PO-based Ising machine were benchmarked against each other for various unweighted and binary-weighted problem graphs of different sizes and connectivity from the Gset Library. In particular, all problems from G01 to G64, as well as G67, were solved using the AFS and PO-based Ising machine simulations 100 times. In FIGS. 7A-7G, the histograms for the cut distributions for 7 large-scale 2,000 node problems are shown, which clearly demonstrates the improvement in solution quality when using AFS over PO-based Ising machine. In fact, for some problems, the worst solution identified by the AFS is better than the best solution identified by the PO-based Ising machine. Since the ground state Ising energy or maximum cut value has not been analytically confirmed for many of these problems, the cut values identified by the AFS and PO-based Ising machine were normalized to the best known solutions as Nₛ, which effectively gives the accuracy of the AFS and the PO-based Ising machine compared to the best-known cuts for each problem. Nₛ, along with the range of solutions (also normalized to the best-known cut) is plotted in FIG. 8 for each of the investigated problems solved by the AFS and PO-based Ising machine. As can be seen, the AFS exhibits a higher accuracy and a tighter spread of solutions than PO-based Ising machines for all of the considered Gset problems.

### Example 6. Electronic Example of Transforming Parametric Oscillators into Floquet Nodes

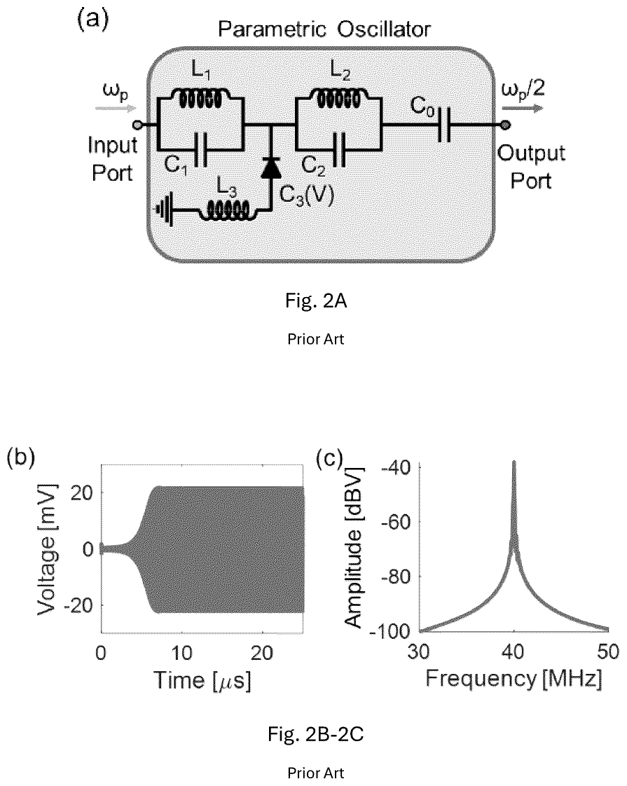

This is an illustrative example in the electronic domain of the changes that must be implemented to a PO to activate Floquet states and transform it into a Floquet node for use in an AFS. Specifically, the design of a parametric frequency divider (PFD, shown in FIG. 2A) is discussed, which is an electronic realization of a parametric oscillator. It will also be shown how inserting a high quality-factor (high Q) resonator, in this case a high-Q microelectromechanical (MEM) resonator, at the output of the PFD activates a Floquet state not attainable without such a resonant device in the PFD's circuit.

PFDs are candidates for use as artificial macroscopic spins in PO-based Ising machines due to the extremely low power (at ωp) required to trigger their subharmonic oscillations (at ωₚ/2) and to synthesize their bistable phase states. The circuital topology of a PFD, as shown in FIG. 2A, includes several branches (Z₁, Z₂, and Z₃). Z₁ hosts the parallel combination of L₁ and C₁, Z₂ contains the parallel combination of L₂ and C₂ in series with C₀, and Z₃ includes the series combination of L₃ and a varactor diode acting as a nonlinear voltage-dependent capacitive element C₃ (V). The component parameters are strategically selected to satisfy the following resonant conditions: Z₁ and Z₃ series resonate at ωp, Z₂ and Z₃ series resonate at ωₚ/2, Z₁ parallel resonates at ωₚ/2, and Z₂ parallel resonates at ωp. These resonant conditions serve to minimize the power threshold required to activate the period doubling regime in the PFDs. More information about the design and optimization of PFDs can be found in [29]. Using a numerical optimization tool within a commercial circuit simulator, these design rules were used to select the following ideal component values, when using a Skyworks SMV1405 diode as C₃(V) and when considering ωₚ/2~100κ (such that fₚ/2=40 MHz): C₁=1.6756 pF, L₁=9.4487 μH, C₂=0.6 pF, L₂=6.5976μH, C₀=2.0 pF, and L₃=4.4937 pH Next, a transient spice simulation was performed when considering a driving signal with frequency ωp (or fp=80 MHz) and a 0.1 Vpp amplitude exceeding the voltage required to activate the period-doubling regime. In FIG. 2B is plotted the time domain evolution of the PFD's output waveform, and the corresponding frequency domain spectrum is plotted in FIG. 2C. Unsurprisingly, it was shown that subharmonic oscillations are activated under such pump conditions, and those subharmonic oscillations remain stable throughout the simulation.

To create a nonlinear electronic system capable of expressing Floquet states using PFDs, a resonant device must be coupled to the PFD's output. Here, a MEM resonator is considered, which is modeled using the Modified Butterworth Van Dyke (mBVD) model (see FIG. 3A). Following [32], [33], the MEM resonator was assumed to have a static capacitance C_{o,s} that matches C₀, an electromechanical coupling kₜ² that closely matches that of the device used in [13], and a quality-factor Qs equal to the quality factor of the mode y used in the numerical studies of the AFS conducted herein. This resonant device was also designed with a resonant frequency fres equal to fₚ/2, or 40 MHz. The equivalent circuit of such a device, as seen in FIG. 3A, can be represented by two parallel branches, one of which features only C_{o,s} while the other, referred to as the motional branch, contains the series combination of the motional resistance Rm, the motional capacitance Cm, and the motional inductance Lm, which collectively capture the MEM resonator's material and operative characteristics. The ideal lumped components values for the designed resonator are: C_{o,s}=2.0 pF, Rm=3.2725 kΩ, Cm=2.43 fF and Lm=6.5104 mH The resonance device can be embedded into the PFD by placing it at the PFD's output such that C_{o,s} replaces C₀, as seen in FIG. 3B. After embedding this resonant device into the PFD's output mesh, the same transient spice simulation from before is repeated, and the time domain waveform and corresponding frequency domain spectra are presented in FIG. 3C and FIG. 3D. As can be seen, the system no longer operates in the period-doubling regime but rather exhibits an activated Floquet state.

Furthermore, the activation of Floquet states occurs due to the addition of a simple RLC circuit to the topology of the PFD presented in FIG. 2A. The simplicity of the modification needed to bring about such an exotic behavioral change in the PFD has enormous ramifications concerning the advantage of using dynamical systems exploiting Floquet dynamics for analog computing. Not only do these Floquet systems exhibit superior computational accuracy compared to their counterparts operating in the period-doubling regime, but an effectively trivial modification that hardly alters the PFD's threshold is the only change required to unlock such a rich dynamical behavior. Even more, the advantage of using Floquet dynamics is manifest in both the classical and quantum domains, as such topological changes can even be used in quantum platforms to realize improved computational performance.

### Example 7. Recurrent Sampling

The reliability of the AFS to reach the best solutions is dependent on the sampling rate fs at which the system's waveforms are sampled and H_{Ising} is computed. In the present analysis, H_{Ising} has been computed at each time-step of the numerical simulation. In the case of 200 node Max-Cut problems, this leads to a value of fs that is approximately equal to 180μ. With such high fs, the H_{Ising} identified by the AFS was tracked with very high fidelity. However, lower values of fs can degrade the resolution of H_{Ising}, which can lead to a less complete evaluation of the values of H_{Ising} identified by the AFS. To help visualize this point, FIG. 9A shows the impact of fs on the solution quality extracted by the AFS by comparing the sampled reconstruction of H_{Ising} when the AFS tackles a randomly generated 200-node 3-regular problem when fs=180P and when fs=9μ. The lower fs led to a degradation in the resolution of H_{Ising} and even caused the AFS to miss certain values of H_{Ising} that were extracted when fs=180p.

Furthermore, the impact of fs was also examined on the solution quality of the AFS for this graph to understand the necessary sampling requirements to ensure that the AFS outperforms the PO-based Ising machine. To do this, the average minimum identified value of H_{Ising} was computed over 100 runs, Hₘᵢₙ, when considering a range of fs between μ/10 and 180μ for both the AFS and the PO-based Ising machine. As expected, Hₘᵢₙ deteriorated as fs decreased when using the AFS but it was unchanged when using the PO-based IM. Yet, for all fs>μ/4, the AFS outperformed the PO-based Ising machine.

### Example 8. Amplitude Heterogeneity in Systems with Modulated Amplitudes

One of the fundamental issues limiting the performance of PO-based Ising machines is amplitude heterogeneity (AH). Each spin in an Ising Hamiltonian is intended to exist in one of two possible states: +1 or −1. In PO-based and, more generally, oscillator-based Ising machines, these states are represented by the phase of each node's output oscillation with respect to some reference. Moreover, the currently existing technology used to implement artificial spins in a wide range of these oscillator-based Ising machine implementations generally introduces an additional degree of freedom, namely amplitude, to the possible spin states. Furthermore, variations in the artificial spin amplitudes can shift the Ising machine's analog energy landscape such that its ground state spin configuration no longer corresponds to the ground state spin configuration of the Ising Hamiltonian.

Therefore, the AH of the PO-based Ising machine was characterized to determine its impact on the identified solution quality. AH was computed for both the AFS and the PO-based Ising machine by taking the coefficient of variation (standard deviation divided by the mean) of the absolute value of the squared spin amplitudes instantaneously throughout each timestep in the computations of both systems. Then, using AH, we calculated A̅H̅, which is a metric we devised to characterize the overall AH for each system. For PO-based IMs, A̅H̅ is taken as the value of AH at the end of the computation, after the system's amplitudes have reached their steady state and the system's phases have converged. However, because the AFS never truly reaches a steady state, we computed A̅H̅ in the AFS by instead averaging AH over two Ising energy modulation periods starting from the first point in which the AFS identifies the minimum Ising energy. By averaging AH in this way, it is possible to capture the impact of the modulation dynamics, like heterogeneities in amplitude envelopes and modulation depths, on the system's “overall” level of AH. A̅H̅ was computed for every single run of every problem.

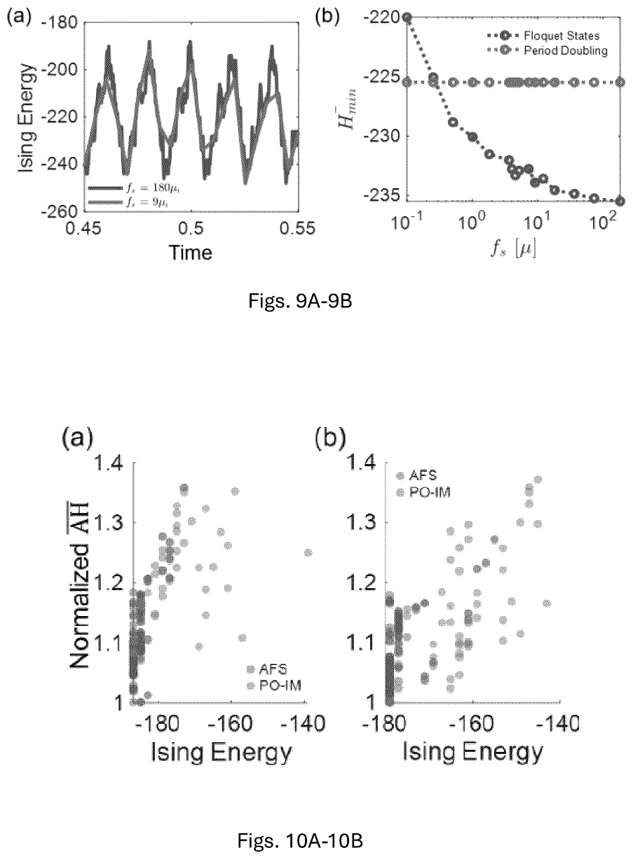

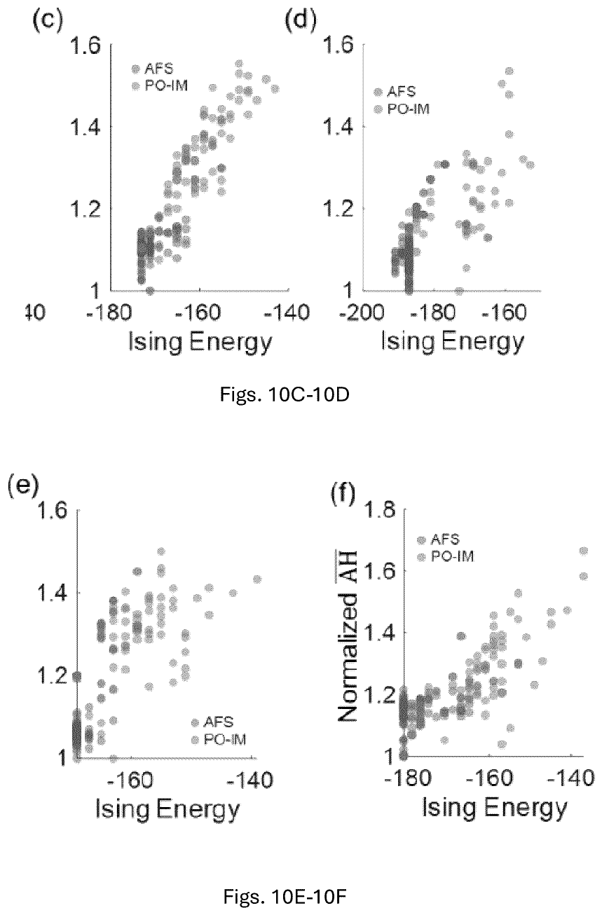

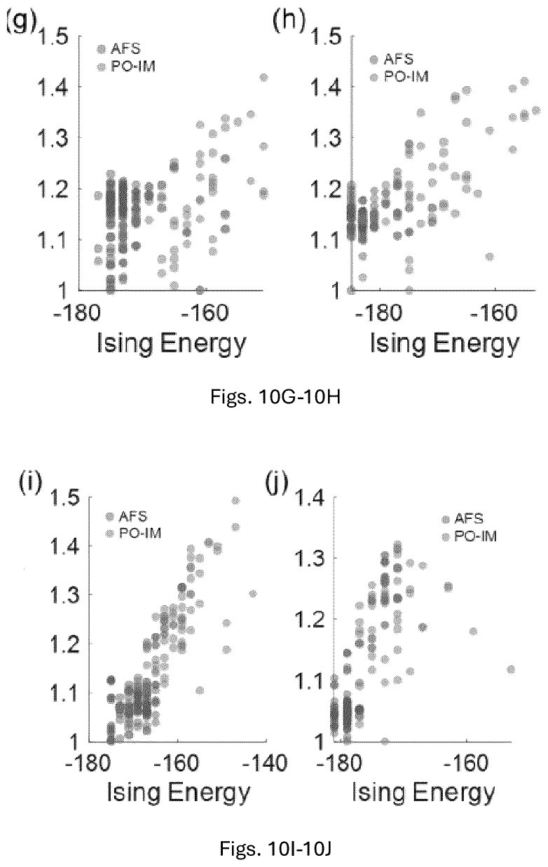

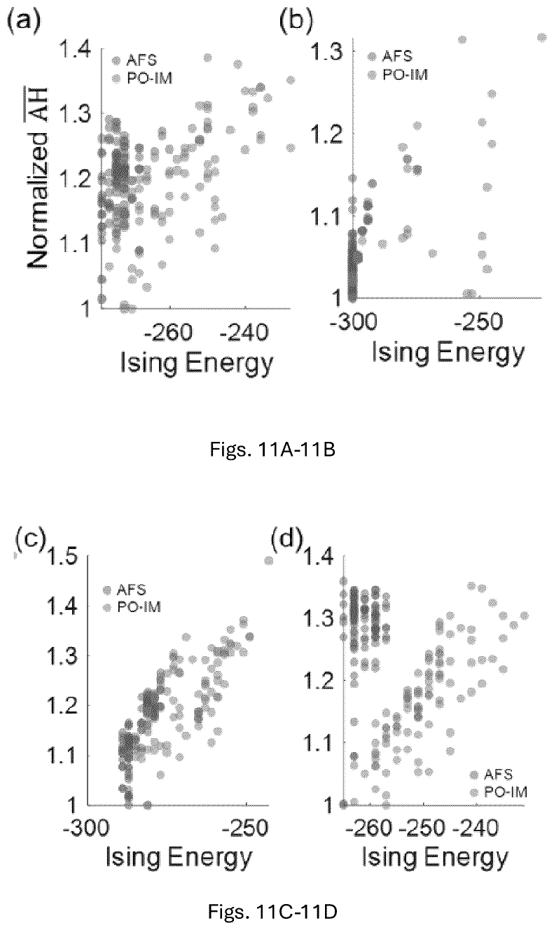

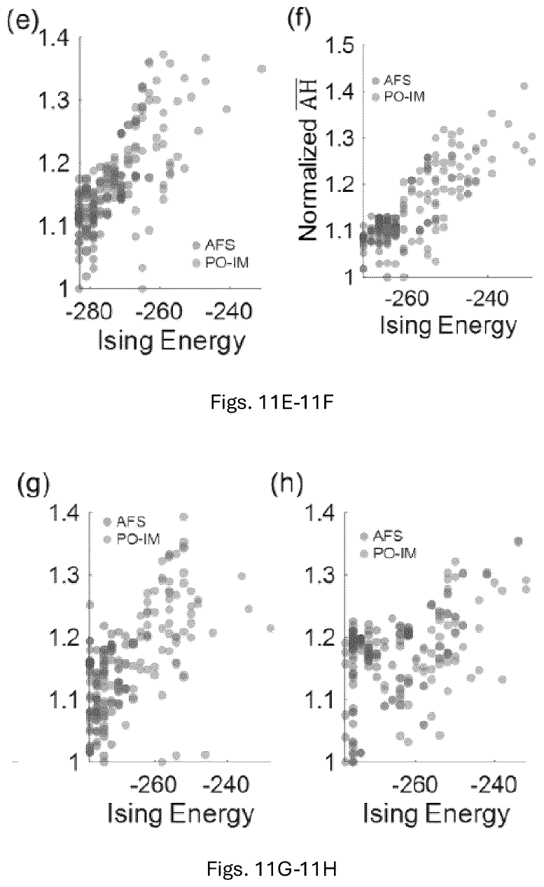

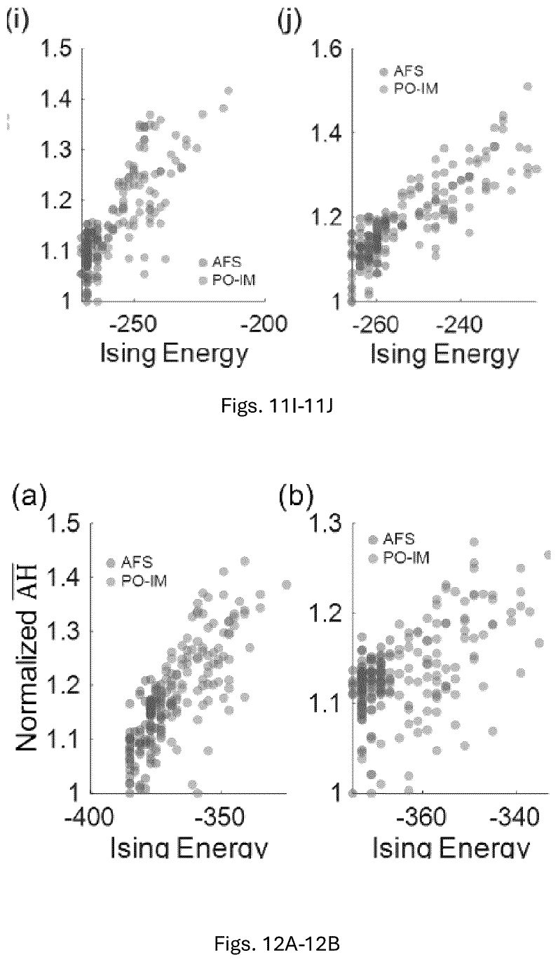

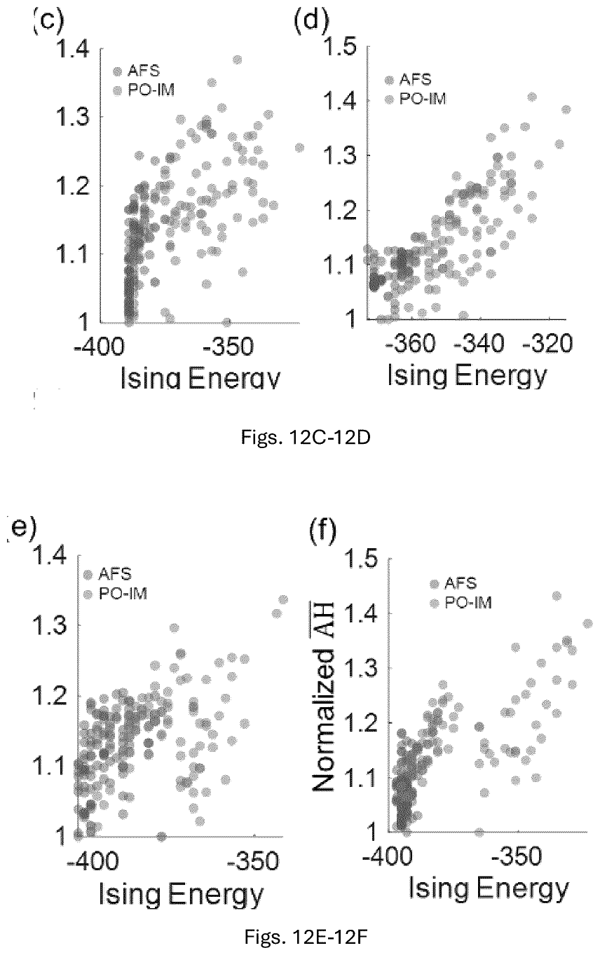

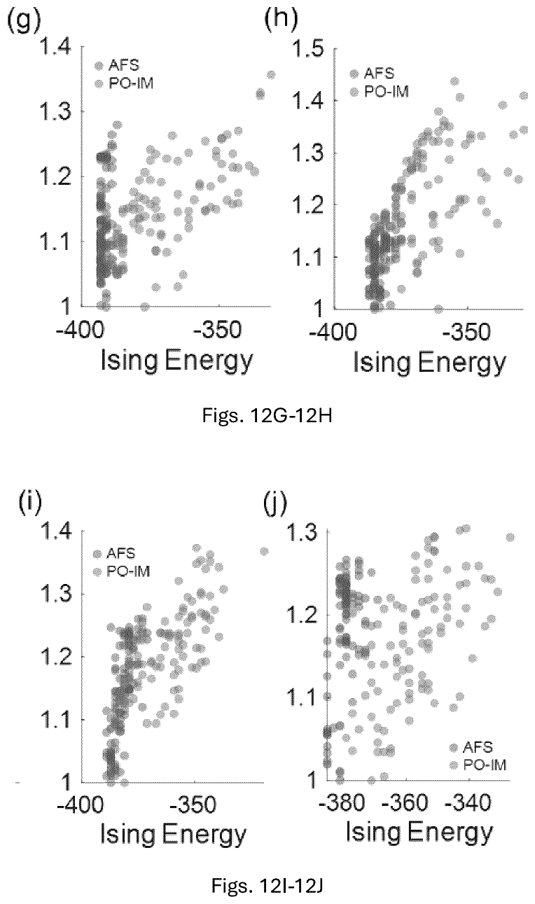

All A̅H̅ were plotted as a scatterplot against the minimum calculated Ising energy for every single run for the BiqMac problems investigated above for both machines. Due to differences in the gain saturation coefficients used in the modelling of the AFS and the PO-based Ising machine, the extracted A̅H̅ values were normalized with respect to the minimum AH computed throughout the 100 runs in each problem and for each machine. In this way, plotting the normalized A̅H̅ also serves to more clearly frame the relationship between A̅H̅ and Ising energy and illustrate how deviations from some “baseline” A̅H̅ impact the calculated Ising energy. FIGS. 10A-10J, 11A-11J, and 12A-12J show the relationship between the normalized A̅H̅ and the Ising energy for both the AFS and the PO-based Ising machine for the investigated BiqMac problems. As can be seen, there was a stronger direct correlation between A̅H̅ and Ising energy for the PO-based Ising machine; those run instances with higher computed Ising energies also generally had higher or worsened A̅H̅. However, this relationship was less sensitive for the AFS, indicating some degree of suppression of the impact of amplitude heterogeneity on the system's ability to access lower Ising energy levels.

### Example 9. Types of Errors Encountered by Dynamical Solvers

Broken mapping [41] is a misalignment between the energy landscape of the Ising Hamiltonian and the analog energy landscape of the dynamical system. This misalignment occurs due to the additional degree of freedom, being the oscillation amplitude, of the artificial spins used to represent Ising spins in systems like PO-based Ising machines. As such, the system's amplitude dynamics play a role in the energy minimization process, which seeks to minimize the analog energy rather than the Ising energy. In the pursuit of the global minima of the analog energy landscape, the system's spin amplitudes may consequently become heterogeneous. When amplitude deviations are relatively low, the global and local minima solutions encoded in the artificial spins' phase configuration generally map to the corresponding minima solutions in the Ising energy. However, the analog system may follow gradient descent trajectories sufficiently displaced by deviations in the spins' amplitude such that the final solutions encoded in the artificial spins' phase configuration no longer necessarily map to Ising energy minima.

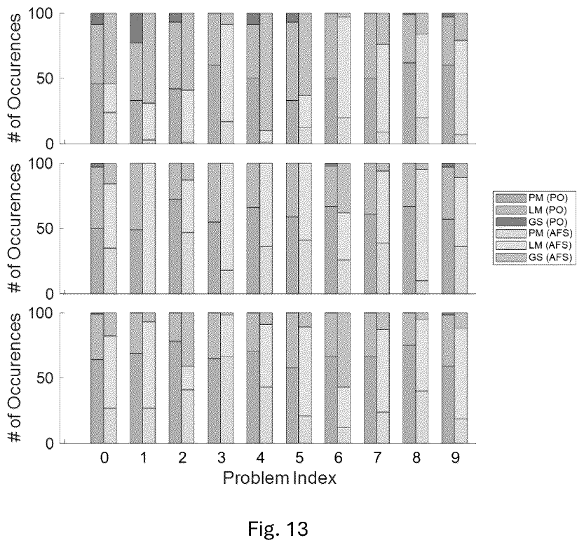

To demonstrate the misalignment of the analog and digital energy convergence trajectories, the BiqMac benchmarking set was used to analyze the maximum cut solutions identified by the PO-based Ising machine and the AFS throughout each run for every problem. For each of the 100 runs per problem, the solutions are differentiated into three distinct categories: ground state (63) solutions, local minima (LM) solutions, and phantom minima (PM) solutions. All of the cut values equal to the analytically determined maximum cut are categorized as GS solutions. An LA solution is defined as a cut whose value does not increase when flipping the sign of one of its spins, and a PM solution is defined as a cut whose value does increase when flipping the sign of one of its spins. The term “phantom minima” is used to describe this type of solution because the amplitude and phase configuration of the artificial spins is likely to identify a local or global minimum in the analog energy landscape, whereas it clearly does not in the digital Ising energy landscape. FIG. 13 shows the distribution of these solution types in stacked bar charts for the AFS and the PO-based IM across all 30 investigated BiqMac problems. As seen in FIG. 13, in almost all problem instances the AFS computes fewer PM solutions and more GS solutions.

As used herein, “consisting essentially of” allows the inclusion of materials or steps that do not materially affect the basic and novel characteristics of the claim. Any recitation herein of the term “comprising”, particularly in a listing of components of a composition or elements of a device, constitutes inclusion of alternative embodiments in which “comprising” is replaced with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

### REFERENCES

[1]D. De Santis, S. Tirone, S. Marmi, and V. Giovannetti, “Optimized QUBO formulation methods for quantum computing,” 2024, arXiv. doi: 10.48550/A RXIV.2406.07681.
[2]F. Glover, G. Kochenberger, R. Hennig, and Y. Du, “Quantum bridge analytics I: a tutorial on formulating and using QUBO models,” Ann Oper Res, vol. 314, no. 1, pp. 141-183, July 2022, doi: 10.1007/s10479-022-04634-2.
[3] H. Goto et al., “High-performance combinatorial optimization based on classical mechanics,” Sci. Adv., vol. 7, no. 6, p. eabe7953, Febuary 2021, doi: 10.1126/sciadv.abe7953.
[4]G. Dominijanni et al., “The neural resource allocation problem when enhancing human bodies with extra robotic limbs,” Nat Mach Intell, vol. 3, no. 10, pp. 850-860, October 2021, doi: 10.1038/s42256-021-00398-9.
[5]A. Perdomo-Ortiz et al., “Readiness of Quantum Optimization Machines for Industrial Applications,” Phys. Rev. Applied, vol. 12, no. 1, p. 014004, July 2019, doi: 10.1103/PhysRevApplied.12.014004.
[6]M. J. A. Schuetz, J. K. Brubaker, and H. G. Katzgraber, “Combinatorial optimization with physics-inspired graph neural networks,” Nat Mach Intell, vol. 4, no. 4, pp. 367-377, April 2022, doi: 10.1038/s42256-022-004686.
[7]A. Merchant, S. Batzner, S. S. Schoenholz, M. Aykol, G. Cheon, and E. D. Cubuk, “Scaling deep learning for materials discovery,” Nature, vol. 624, no. 7990, pp. 80-85, December 2023, doi: 10.1038/s41586-023-06735-9.
[8]A. V. Sadybekov and V. Katritch, “Computational approaches streamlining drug discovery,” Nature, vol. 616, no. 7958, pp. 673-685, April 2023, doi: 10.1038/s41586-023-05905z.
[9]E. Pelofske, G. Hahn, and H. N. Djidjev, “Increasing the hardness of posiform planting using random QUBOs for programmable quantum annealer benchmarking,” npj Unconv. Comput., vol. 2, no. 1, p. 17, July 2025, doi: 10.1038/s44335-025-00032-6.
[10]M. X. Goemans and D. P. Williamson, “Improved approximation algorithms for maximum cut and satisfiability problems using semidefinite programming,” J. ACM, vol. 42, no. 6, pp. 1115-1145, November 1995, doi: 10.1145/227683.227684.
[11]E. Farhi, J. Goldstone, and S. Gutmann, “A Quantum Approximate Optimization Algorithm,” 2014, arXiv. doi: 10.48550/ARXIV.1411.4028.
[12]R. Nieuwenhuis, A. Oliveras, and C. Tinelli, “Solving SAT and SAT Modulo Theories: From an abstract Davis—Putnam—Logemann-Loveland procedure to DPLL ACM, vol. 53, no. 6, pp. 937-977, November 2006, doi: 10.1145/1217856.1217859.
[13][13]D. J. Gauthier, E. Bollt, A. Griffith, and W. A. S. Barbosa, “Next generation reservoir computing,” Nat Commun, vol. 12, no. 1, p. 5564, September 2021, doi: 10.1038/s41467-021-25801-2.
[14]D. Kudithipudi et al., “Neuromorphic computing at scale,” Nature, vol. 637, no. 8047, pp. 801-812, January 2025, doi:10.1038/s41586-024-08253-8.
[15]T. D. Ladd, F. Jelezko, R. Laflamme, Y. Nakamura, C. Monroe, and J. L. O'Brien, “Quantum computers,” Nature, vol. 464, no. 7285, pp. 45-53, March 2010, doi: 10.1038/nature08812.
[16]Y. Yamamoto et al., “Coherent Ising machines-optical neural networks operating at the quantum limit,” npj Quantum Inf, vol. 3, no. 1, p. 49, December 2017, doi: 10.1038/s41534-017-0048-9.
[17]N. Mohseni, P. L. McMahon, and T. Byrnes, “Ising machines as hardware solvers of combinatorial optimization problems,” Nat Rev Phys, vol. 4, no. 6, pp. 363-379, May 2022, doi:10.1038/s42254-022-00440-8.
[18]O. Maher et al., “A CMOS-compatible oscillation-based V02 Ising machine solver,” Nat Commun, vol. 15, no. 1, p. 3334, April 2024, doi: 10.1038/s41467-024-47642-5.
[19]H. Cilasun et al., “A coupled-oscillator-based Ising chip for combinatorial optimization,” Nat Electron, vol. 8, no. 6, pp. 537-546, June 2025, doi:10.1038/s41928-025-01393-3.
[20]G. F. Newell and E. W. Montroll, “On the Theory of the Ising Model of Ferromagnetism,” Rev. Mod. Phys., vol. 25, no. 2, pp. 353-389, April 1953, doi: 10.1103/RevModPhys.25.353.
[21]F. Barahona, “On the computational complexity of Ising spin glass models,” J. Phys. A: Math. Gen., vol. 15, no. 10, pp. 3241-3253, October 1982, doi:10.1088/0305-4470/15/10/028.
[22]S. Nikhar, S. Kannan, N. A. Aadit, S. Chowdhury, and K. Y. Camsari, “All-to-all reconfigurability with sparse and higher-order Ising machines,” Nat Commun, vol. 15, no. 1, p. 8977, October 2024, doi: 10.1038/s41467-024-53270-w.
[23]K. Tatsumura, M. Yamasaki, and H. Goto, “Scaling out Ising machines using a multi-chip architecture for simulated bifurcation,” Nat Electron, vol. 4, no. 3, pp. 208-217, March 2021, doi: 10.1038/s41928-021-00546-4.
[24]N. A. Aadit et al., “Massively parallel probabilistic computing with sparse Ising machines,” Nat Electron, vol. 5, no. 7, pp. 460-468, June 2022, doi:10.1038/s41928-022-00774-2.
[25]K. Lee, S. Chowdhury, and K. Y. Camsari, “Noise-augmented chaotic Ising machines for combinatorial optimization and sampling,” Commun Phys, vol. 8, no. 1, p. 35, January 2025, doi:10.1038/s42005-025-01945-1.
[26]N. Casilli, S. Kim, S. Mittal, M. Onabajo, A. Alu, and C. Cassella, “Supplementary Material for ‘Floquet-Based Ising Machines Escape Local Minima in QUBO Problems.’”
[27]M. Calvanese Strinati and C. Conti, “Multidimensional hyperspin machine,” Nat Commun, vol. 13, no. 1, p. 7248, November 2022, doi:10.1038/s41467-022-34847-9.
[28]T. Wang and J. Roychowdhury, “OIM: Oscillator-based Ising Machines for Solving Combinatorial Optimisation Problems,” 2019, doi:10.48550/ARXIV.1903.07163.
[29]R. Hamerly et al., “Experimental investigation of performance differences between coherent Ising machines and a quantum annealer,” Sci. Adv., vol. 5, no. 5, p. eaau0823, May 2019, doi:10.1126/sciadv.aau0823.
[30]Y. Okawachi et al., “Demonstration of chip-based coupled degenerate optical parametric oscillators for realizing a nanophotonic spin-glass,” Nat Commun, vol. 11, no. 1, p. 4119, August 2020, doi: 10.1038/s41467-020-17919-6.
[31]D.-W. Quantum, “Get Started with Quantum Computing.” D-Wave Quantum. Accessed: Mar. 18, 2026. [Online]. Available: dwavequantum.com/en/latest/quantum_research/index get_started.html
[32]N. Casilli, T. Kaisar, L. Colombo, S.Ghosh, P. X.-L. Feng, and C. Cassella,” Parametric Frequency Divider Based Ising Machines,” Phys. Rev. Lett., vol. 132, no. 14, p. 147301, April 2024, doi:10.1103/PhysRevLett.132.147301.
[33]B. Wu et al., “A monolithically integrated optical Ising machine,” Nat Commun, vol. 16, no. 1, p. 4296, May 2025, doi: 10.1038/s41467-025-59537-0.
[34]L. Q. English, A. V. Zampetaki, K. P. Kalinin, N. G. Berloff, and P. G. Kevrekidis, “An Ising machine based on networks of subharmonic electrical resonators,” Commun Phys, vol. 5, no. 1, p. 333, December 2022, doi:10.1038/s42005-022-01111-x.
[35]Y. Okawachi et al., “Demonstration of chip-based coupled degenerate optical parametric oscillators for realizing a nanophotonic spin-glass,” Nat Commun, vol. 11, no. 1, p. 4119, August 2020, doi: 10.1038/s41467-020-17919-6.
[36]N. Casilli et al., “Programmable threshold sensing in wireless devices using Ising dynamics,” Nat Electron, June 2025, doi: 10.1038/s41928-025-01392-4.
[37]M. Calvanese Strinati, L. Bello, A. Pe'er, and E. G. Dalla Torre, “Theory of coupled parametric oscillators beyond coupled Ising spins,” Phys. Rev. A, vol. 100, no. 2, p. 023835, August 2019, doi:10.1103/PhysRevA.100.023835.
[38]Y. Chen, X. Chen, X. Ren, M. Gong, and G. Guo, “Tight-binding model in optical waveguides: Design principle and transferability for simulation of complex photonics networks,” Phys. Rev. A, vol. 104, no. 2, p. 023501, August 2021, doi:10.1103/PhysRevA.104.023501.
[39]H. M. E. Hussein, M. A. A. Ibrahim, G. Michetti, M. Rinaldi, M. Onabajo, and C. Cassella, “Systematic Synthesis and Design of Ultralow Threshold 2:1 Parametric Frequency Dividers,” IEEE Trans. Microwave Theory Techn., vol. 68, no. 8, pp. 3497-3509, August 2020, doi: 10.1109/TMTT.2020.2999790.
[40]H. M. E. Hussein, S. Kim, M. Rinaldi, A. Alù, and C. Cassella, “Passive frequency comb generation at radiofrequency for ranging applications,” Nat Commun, vol. 15, no. 1, p. 2844, April 2024, doi:10.1038/s41467-024-46940-2.
[41]I. Mahboob, H. Okamoto, and H. Yamaguchi, “An electromechanical Ising Hamiltonian,” Sci. Adv., vol. 2, no. 6, p. e1600236, June 2016, doi:10.1126/sciadv.1600236.
[42]S. Razmkhah, M. Kamal, N. Yoshikawa, and M. Pedram, “Josephson parametric oscillator based Ising machine,” Phys. Rev. B, vol. 109, no. 1, p. 014511, January 2024, doi:10.1103/PhysRevB.109.014511.
[43]C. Gneiting, F. Khoyratee, E. Rinaldi, K. Jain, R. Khincha, and F. Nori, “Noise resilience of deterministic analog combinatorial optimization solvers,” 2025, arXiv. doi:10.48550/ARXIV.2506.12914.
[44]J. Roychowdhury, “A global Lyapunov function for the coherent Ising machine,” NOLTA, vol. 13, no. 2, pp. 227-232, 2022, doi:10.1587/nolta.13.227.
[45]S. K. Vadlamani, T. P. Xiao, and E. Yablonovitch, “Physics successfully implements Lagrange multiplier optimization,” Proc. Natl. Acad. Sci. U.S.A., vol. 117, no. 43, pp. 26639-26650, October 2020, doi:10.1073/pnas.2015192117.
[46]Z. Chen et al., “ON-OFF neuromorphic ISING machines using Fowler-Nordheim annealers,” Nat Commun, vol. 16, no. 1, p. 3086, March 2025, doi:10.1038/s41467-025-58231-5.
[47]A. Wiegele, “Biq Mac Library—A collection of Max-Cut and quadratic 0-1 programming instances of medium size.” [Online]. Available: biqmac.aau.at/biqmaclib.pdf
[48]M.-A. Miri and A. A10, “Nonlinearity-induced PT-symmetry without material gain,” New J. Phys., vol. 18, no. 6, p. 065001, May 2016, doi:10.1088/1367-2630/18/6/065001.
[49]N. Tsuji, “Floquet states,” in Encyclopedia of Condensed Matter Physics, Elsevier, 2024, pp. 967-980. doi: 10.1016/B978-O-323-90800-9.00241-9.
[50]D. J. Higham, “An Algorithmic Introduction to Numerical Simulation of Stochastic Differential Equations,” SIAM Rev., vol. 43, no. 3, pp. 525-546, January 2001, doi: 10.1137/S0036144500378302.
[51]M. Honari-Latifpour and M.-A. Miri, “Optical Potts machine through networks of three-photon down-conversion oscillators,” Nanophotonics, vol. 9, no. 13, pp. 4199-4205, July 2020, doi: 10.1515/nanoph-2020-0256.
[52]M. Honari-Latifpour, M. S. Mills, and M.-A. Miri, “Combinatorial optimization with photonics-inspired clock models,” Commun Phys, vol. 5, no. 1, p. 104, April 2022, doi: 10.1038/s42005-022-00874-7.
[53]A. Litvinenko, R. Khymyn, R. Ovcharov, and J. Akerman, “A 50-spin surface acoustic wave Ising machine,” Commun Phys, vol. 8, no. 1, p. 58, February 2025, doi: 10.1038/s42005-025-01969-7.
[54]R. Shi, F. Böhm, T. Van Vaerenbergh, and P. Bienstman, “Enhancing the performance of coherent Ising machines in the large-noise regime with a fifth-order nonlinearity,” Opt. Express, vol. 32, no. 12, p. 21681, June 2024, doi: 10.1364/oe.522474.

What is claimed is:

1. An analog circuit comprising a parametric oscillator coupled to a passive resonance device, wherein the circuit produces a frequency comb output in response to a pump signal input, and wherein the frequency comb comprises a Floquet state.

2. The analog circuit of claim 1, wherein the Floquet state comprises periodic amplitude modulation of the frequency comb.

3. The analog circuit of claim 1, which is electronic, electromagnetic, photonic, mechanical, acoustic, or a combination thereof.

4. The analog circuit of claim 3, wherein the circuit is electronic and the parametric oscillator is a parametric frequency divider.

5. The analog circuit of claim 1, wherein the passive resonance device has a resonance frequency within 2% of that of the parametric oscillator.

6. The analog circuit of claim 4, wherein the passive resonance device has a resonance frequency essentially the same as that of the parametric oscillator.

7. The analog circuit of claim 4, wherein the parametric frequency divider comprises a pair of parametric oscillators coupled at their junction to a nonlinear component comprising a varactor and an inductor, and the output signal of the analog circuit is a frequency comb having a frequency that is half of a frequency of the pump signal.

8. The analog circuit of claim 1, wherein the passive resonance device comprises one or more of a microelectromechanical (MEM) resonator, a piezoelectric resonator, a quartz resonator, a photonic resonator, an optomechanical resonator, a magnonic resonator, a spintronic resonator, or a resonant circuit.

9. The analog circuit of claim 1, wherein the passive resonance device has a quality factor of at least five times higher than that of the parametric oscillator, or at least 500.

10. The analog circuit of claim 1 that resides in a chip, sensor, signal processing circuit, analog computer, or quantum computer.

11. An analog computing device comprising a plurality of the analog circuits of claim 1 configured as a coupled spin network, wherein each analog circuit serves as a node of the network.

12. The analog computing device of claim 11 which is capable of solving a quadratic unconstrained binary optimization problem while avoiding local minima.

13. The analog computing device of claim 11, wherein the device has 10 or more nodes, or 100 or more nodes.

14. The analog computing device of claim 11, wherein the analog circuits of the device operate passively and do not use DC biasing.

15. The analog computing device of claim 11 that is implemented in a chip, sensor, analog computer, or quantum computer.

16. The analog computing device of claim 11, wherein coupling weights between the nodes are reprogrammable.

17. The analog computing device of claim 11, wherein power consumption is in the nanowatt range for each of the analog circuits.

18. A method of designing an analog computing device, comprising the steps of:
providing a quadratic unconstrained binary optimization problem, which is characterized by a plurality of binary variables (spins) and can be solved by determining an arrangement of spins that provides a ground state energy level,
mapping the problem variables to the spins;
designing the analog computing device, wherein the device comprises a network of interconnected nodes, and assigning interaction strengths between nodes for solving the problem, wherein each node comprises an analog circuit of claim 1.

19. The method of claim 18, wherein the problem is a problem in finance, economics, healthcare, drug discovery, material discovery, or machine learning.

20. A method of operating an analog computing device to solve a quadratic unconstrained binary optimization problem, the method comprising:
providing the analog computing device of claim 11, wherein the device is designed to solve the quadratic unconstrained binary optimization problem; and
operating the analog computing device to find the lowest energy state, wherein two or more nodes minimize their collective Hamiltonian during phase synchronization.
